(19) United States
(12) Patent Application Publication
(10) Pub. No.: US 2011/0255698 A1
(43) Pub. Date: Oct. 20, 2011

(54) PROGRAMMABLE NOISE GATE FOR AUDIO AMPLIFIER EMPLOYING A COMBINATION OF LOW-NOISE AND NOISE-REJECTING ANALOG AND DIGITAL SIGNAL PROCESSING

(76) Inventor: Hubert Young, Colorado Springs, CO (US)

(21) Appl. No.: 13/083,018

(22) Filed: Apr. 8, 2011

Related U.S. Application Data
(60) Provisional application No. 61/325,420, filed on Apr. 19, 2010.

(51) Int. Cl. H03G 3/00; H04R 5/00

(52) U.S. Cl. 381/28; 381/107

(57) ABSTRACT

An apparatus comprises a first signal circuit path, a noise gate circuit, and a control circuit. The first signal circuit path processes a first electrical signal that includes one or more signal frequencies in the audio frequency band. The first signal circuit path includes a first amplifier circuit configured to provide a first output signal to a speaker load. The noise gate circuit monitors the first electrical signal and generates a first indication when the amplitude of the first electrical signal decreases below a first specified threshold voltage value. The control circuit mutes an output of the first signal circuit path according to the generated indication. The apparatus is formed on a single integrated circuit.

### CLAIM OF PRIORITY

This application claims the benefit of priority under 35 U.S.C. §119(e) to Young III, U.S. Provisional Application Ser. No. 61/325,420, entitled “A PROGRAMMABLE NOISE GATE FOR AUDIO AMPLIFIER EMPLOYING A COMBINATION OF LOW-NOISE AND NOISE-REJECTING ANALOG AND DIGITAL SIGNAL PROCESSING,” filed on Apr. 11, 2010 (Attorney Docket No. 2921.070PRV), which is incorporated herein by reference in its entirety.

### BACKGROUND

Personal electronic devices include MP3 portable media players, cellular phones, and smart phones. Convenience of the devices stems in part from the functionality they provide despite their small size. Because the devices are battery powered, there can be a design tradeoff between size and the amount of operating time before batteries need to be replaced. It is desirable to continue to provide more functionality in such devices even though it is desired to keep the devices at their same small size or to make them even smaller.

One way to decrease the size of devices is to consolidate device functions into a fewer number of parts. Some integrated circuits (ICs) can provide both digital and analog functions. Such ICs can be called mixed signal ICs. However, switching noise from the digital functionality and noise from switching power functions can add undesirable circuit noise that can degrade the performance of the analog circuits.

### Overview

According to various embodiments, the inventive subject matter covers volume control circuit architecture including automatic gain control, zero crossing, ramping and a noise gate circuit.

An apparatus that is formed on a single integrated circuit comprises a first signal circuit path, a noise gate circuit, and a control circuit. The first signal circuit path processes a first electrical signal that includes one or more signal frequencies in the audio frequency band. The first signal circuit path includes a first amplifier circuit configured to provide a first output signal to a speaker load. The noise gate circuit monitors the first electrical signal and generates a first indication when the amplitude of the first electrical signal decreases below a first specified threshold voltage value. The control circuit mutes an output of the first signal circuit path according to the generated indication. The apparatus is formed on a single integrated circuit.

This section is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a flow diagram of an example of a method to reduce noise on an audio signal circuit path of a single mixed signal IC.

FIG. 2 shows a block diagram of portions of an example of a single mixed signal IC that includes audio amplifiers.

FIG. 3 shows a block diagram of an example of a noise gate circuit.

FIG. 4 shows a time domain simulation of the function of the noise gate circuit.

FIG. 5 shows a frequency domain simulation of the function of the noise gate circuit.

FIG. 6 shows an example of a switched capacitor divider circuit.

FIG. 7 shows another a block diagram of another example of a noise gate circuit.

FIG. 8 shows an example of a circuit for threshold detection for automatic gain control.

FIG. 9 shows an example of variation of an automatic gain control threshold with battery voltage.

FIG. 10 shows an example simulation of an example of volume control function.

FIG. 11 shows another example simulation of an example of volume control function.

FIG. 12 shows a zoomed-in portion of the simulation of FIG. 11.

### DETAILED DESCRIPTION

This document relates generally to electronic audio amplifiers and in particular to volume control circuit architecture including automatic gain control, zero crossing, ramping, and a noise gate circuit. Amplifiers can be used to drive a low impedance load (e.g., a speaker or a set of headphones). Incorporating digital functions and audio amplifiers on the same IC can degrade performance of the amplifiers.

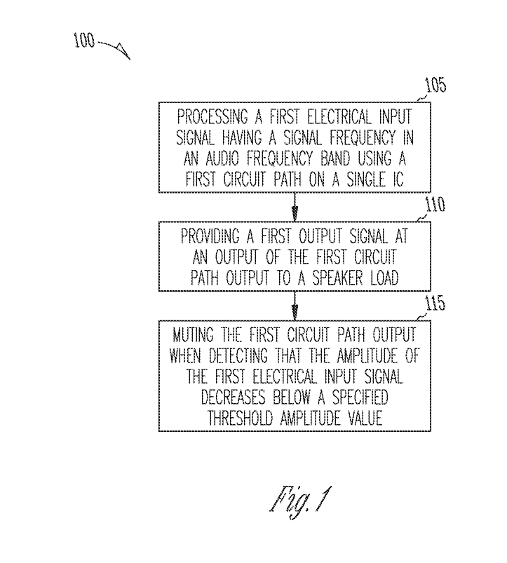

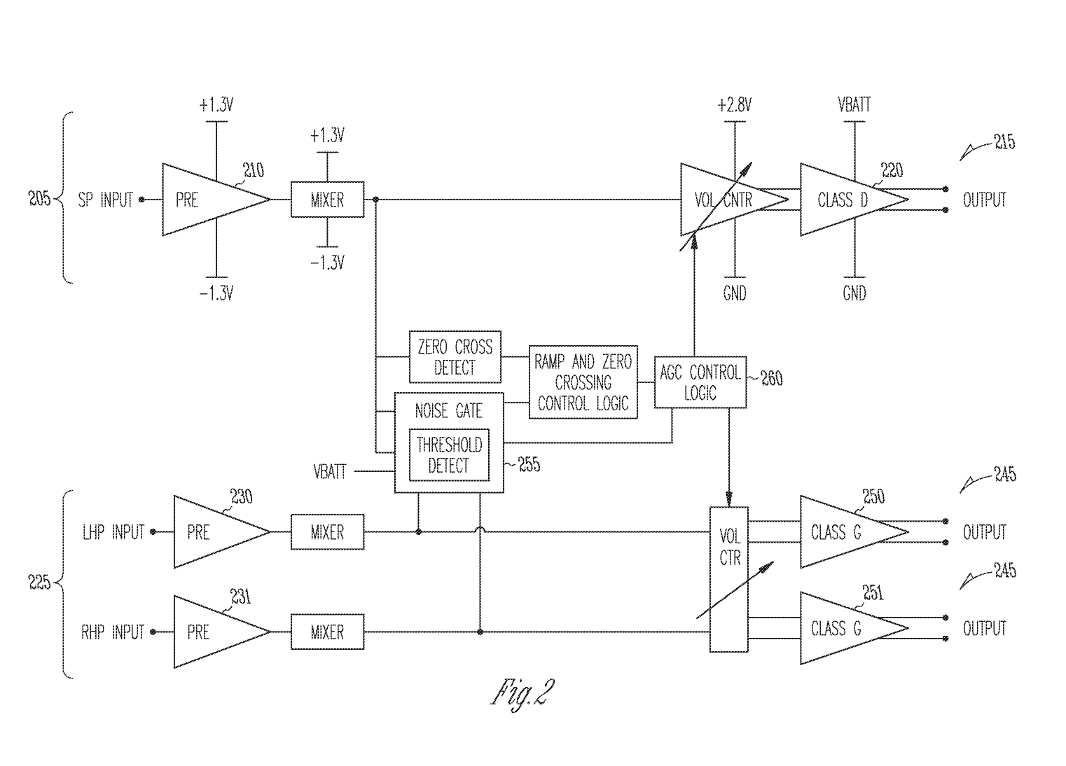

FIG. 1 is a flow diagram of an example of a method 100 to reduce noise on an audio signal circuit path of a single mixed signal IC. In some examples, the method is incorporated into volume control circuit architecture of a device such as a cell phone or a personal media player.

At block 105, a first electrical input signal having a signal frequency in an audio frequency band is processed using a first circuit path on a single IC. In some examples, the input signal is provided from another stage of a volume control circuit, such as a mixing stage or a preamplifying stage. At block 110, a first output signal is provided at an output of the first circuit path to a speaker load.

At block 115, the first circuit path output is muted when detecting that the amplitude of the first electrical input signal decreases below a specified threshold amplitude value. In some examples, the first electrical signal can be a differential electrical signal processed by a differential amplifier, and muting the circuit path output includes electrically connecting together the differential inputs of the amplifier. In some examples, muting the circuit path output includes setting the differential inputs of the amplifier to zero volts. In some examples, the first electrical signal is processed by a volume control circuit and muting the circuit path output includes setting the volume control circuit to the lowest gain setting.

The result of muting the output is to pass the amplifier noise-floor level to the circuit output, which is quieter than the ambient noise of a typical audio signal path. This can eliminate hiss when no signal or an extremely small amplitude signal is present. The output can be unmuted when the amplitude of the input signal exceeds the specified threshold amplitude value.

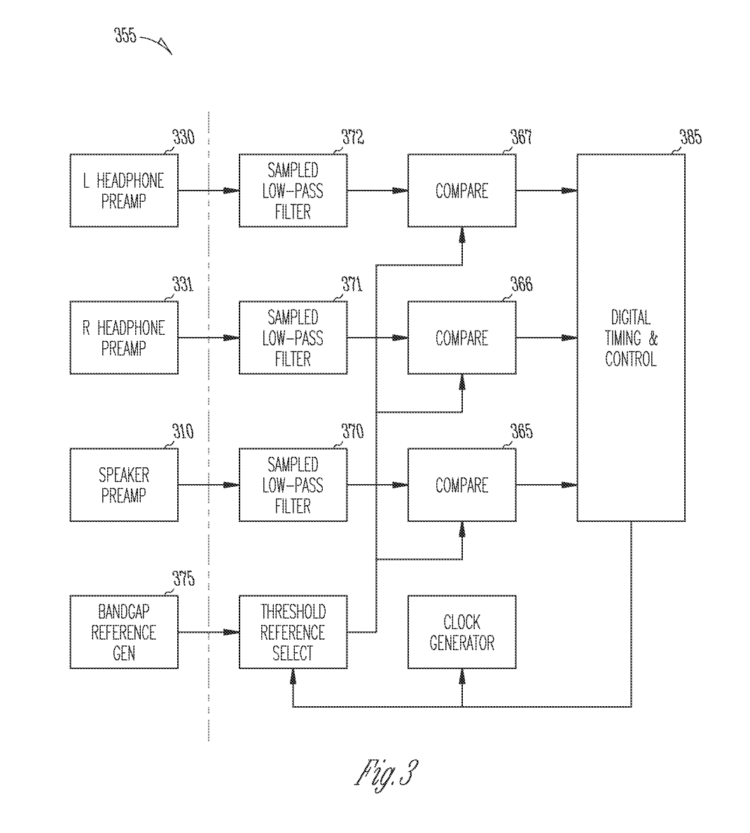

FIG. 2 shows a block diagram of portions of an example of a single mixed signal IC that includes audio amplifiers. The IC includes a first circuit path. The first circuit path 205 processes a first electrical input signal that includes one or more signal frequencies included in the audio band of frequencies. In some examples, first circuit path 205 processes an electrical signal that includes one or more signal frequencies form twenty Hertz to 20,000 Hertz (20 Hz-20 kHz). In some examples, the first circuit path 205 processes electrical signals having amplitudes in the range of 2.8 millivolts peak (mVpk) to 181 mVpk. The input signal can be provided by a preamplifier 210 and/or a mixer that may be included in the single IC.

The first circuit path 205 includes a first circuit path output 215 and an amplifier circuit 220 that provides a first output signal at the first circuit path output. In some examples, the amplifier circuit 220 provides a first output signal at the first circuit path output 215 to drive a speaker. The amplifier circuit 220 can be a switching amplifier circuit (e.g., a class D amplifier circuit). In certain examples, the output drives a low impedance load, such as a 4 ohm (Ω) speaker load for example. In some examples, the first output signal switches a speaker load between a circuit supply voltage (e.g., V_{DD} or V_{BATT}) and IC ground.

The IC also includes a noise gate circuit 255 and a control circuit 260. The noise gate circuit 255 monitors the first electrical signal and generates a first indication (e.g., a logical signal) when an amplitude of the first electrical signal decreases below a first specified threshold voltage value. In certain examples, the noise gate circuit includes a compare circuit (e.g., a comparator or CDS regenerative comparator) to provide an indication when the amplitude of the first electrical signal is less than the first specified threshold voltage value.

The control circuit 260 is communicatively coupled to the noise gate circuit and first signal circuit path 205. The communicative coupling allows the control circuit 260 to receive or send signals to the noise gate circuit 255 and the first circuit path 205 even though there may be intervening circuitry. The control circuit 260 mutes the output of the first signal circuit path 205 according to the generated indication. The control circuit 260 can be a custom logic circuit configured to perform the described function or functions. In some examples, the control circuit 260 includes a processor such as a microprocessor, digital signal processor, or other processor. In some examples, the processor is an IP core (e.g., a reusable processor design) included in the IC. In some examples, the control circuit 260 unmutes the circuit path when the noise gate removes the indication (e.g., when the signal amplitude rises above the threshold), or when the noise gate circuit generates a second indication that the signal amplitude is above the specified threshold.

In certain examples, the control circuit 260 mutes the first circuit path output by electrically connecting the inputs of the amplifier circuit 220 together. In certain examples, the control circuit mutes the circuit path output by setting the inputs of the amplifier circuit 220 to zero volts. In certain examples, the first circuit path includes a volume control circuit 265 and the control circuit 260 mutes the circuit path output by setting a gain of the volume control circuit 265 to the lowest gain setting. In certain examples, the amplifier circuit 220 is a switching amplifier circuit and the control circuit 260 mutes the output of the first circuit path 205 by stopping the switching of the amplifier circuit.

According to some examples, the IC includes a second circuit path 225 to process second and third electrical signals each having a frequency in the audio frequency band. In some examples, the second and third electrical signals are independent, and in some examples the second and third electrical signals form a stereo signal pair (such as a stereo signal pair for stereo headphones). The second and third signals can be provided by preamplifiers 230, 231 and/or signal mixers that can be included in the IC. The second circuit path 225 is independent from the first circuit path 205. This means that the signal amplitude in the second circuit path 225 could be very small (e.g., below 10 mV) while the power delivered by the amplifier of the first circuit path 205 is over one watt (1 W).

The second circuit path 225 includes a second circuit path output 245 that provides second and third output signals. The second circuit path 225 includes a second amplifier circuit 250 and a third amplifier circuit 251 to receive the second and third electrical signals and provide the second and third output signals respectively. In certain examples, the second amplifier circuit 250 and the third amplifier circuit 251 are class G audio amplifier circuits. The IC may include a charge pump circuit communicatively coupled to the second and third amplifier circuits. The charge pump circuit can be a charge pump switching supply circuit that generates a positive supply rail and a negative supply rail for the second and third amplifier circuits. The switching frequency of the charge pump circuit can be variable based on the amplitude of one or both of the second and third electrical signals.

The second circuit path 225 is communicatively coupled to the noise gate circuit 255 and the control circuit 260. If the second and third signals are independent, the noise gate circuit 255 generates a second indication when the amplitude of at least one of the second and third electrical signals decreases below the first specified threshold voltage value or a different second specified threshold voltage value. If the second and third electrical signals form a stereo signal pair, the noise gate circuit 255 generates a second indication when the amplitude of both the second and third electrical signals are below the specified threshold voltage value. In some examples, the noise gate circuit 255 includes additional comparison circuits to detect when one or both of the stereo signal pair decreases below the specified threshold voltage value. The control circuit 260 is configured to mute outputs of the second and third amplifier circuits according to the detection circuit indication.

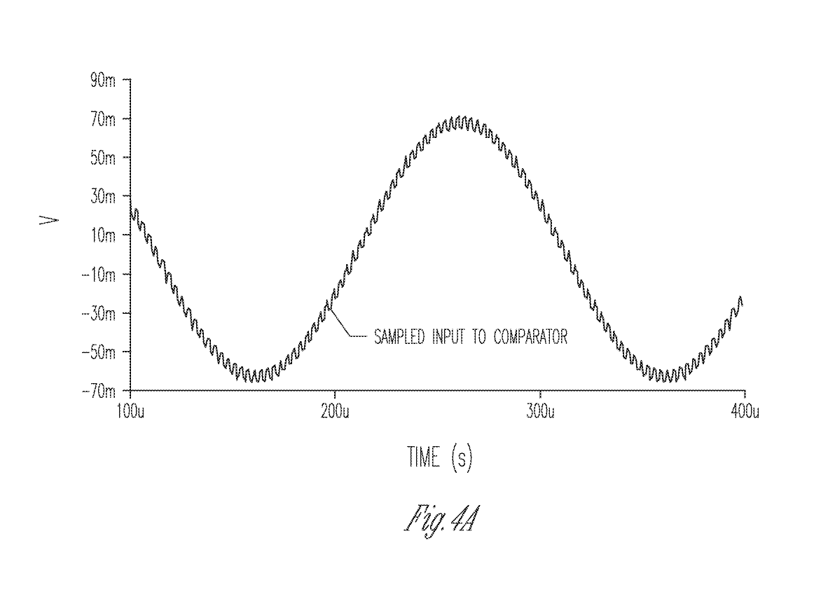

FIG. 3 shows a block diagram of an example of a noise gate circuit 355. The noise gate circuit 355 receives one or more of the first, second, and third electrical signals from preamplifier circuit 310, 330, and 331 respectively. Compare circuits 365, 366, and 367 detect when the amplitude of one or more of the first second and third electrical signals is less than the specified threshold voltage value. In certain examples, different threshold values are specified for detection of low amplitudes in the different signals. In some examples, the threshold voltage values are selectable.

Various switching functions have been described in regard to operation of the circuit, such as a switching amplifier and a switching charge pump circuit. Because the digital and analog circuits are included on one IC, switching noise from digital functions and switching noise from power functions can introduce noise transients. The noise gate circuit 355 includes one or more low pass filters 370, 371, and 372 to filter noise from one or more of the first electrical signal and the stereo signal pair. In some examples, the low pass filters are discrete-time low pass filter circuits.

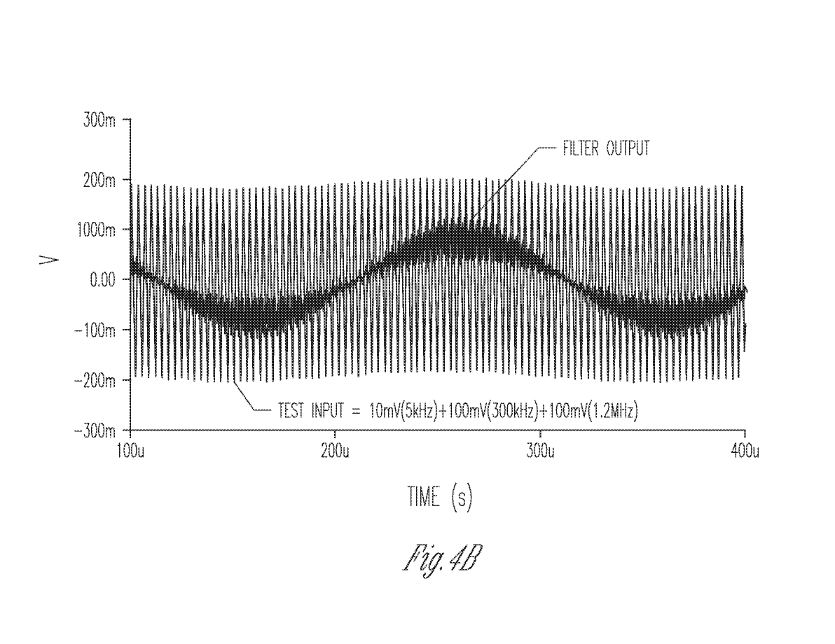

FIG. 4 shows a time domain simulation of the function of the noise gate circuit 355. The lower simulation window shows the noisy input to one of the low pass filters. It can be seen that detection of low amplitude signals on a mixed signal IC would not be possible without filtering. The lower simulation window also shows the output of the filter. The upper simulation window is a display of the output of the filter without the noisy input shown.

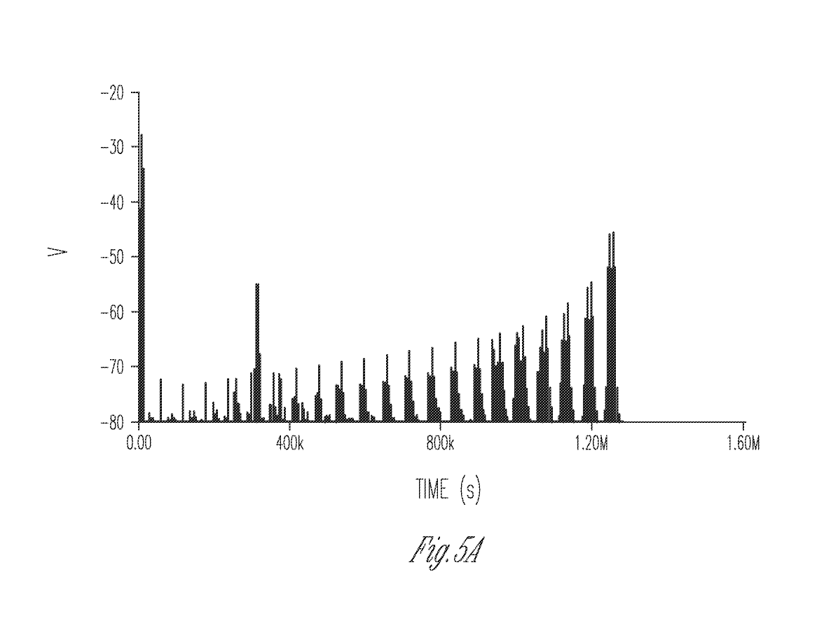

FIG. 5 shows a frequency domain simulation of the function of the noise gate circuit 355. The lower simulation window shows a frequency spectrum of a test input signal to the noise gate circuit 355. The simulation shows that the test input signal includes content in the audio band (approximately 10 kHz at −48 dBV) and also includes two switching components of −28 dBV at about 300 kHz (actually 312.5 kHz) and of −28 dBV at about 1.2 MHz (closer to 1.25 MHz). Note that switching noise content has a larger magnitude than the audio content.

The upper simulation window is the output of the discrete-time low pass filter circuit 370. The simulation shows that the 10 kHz audio content of the input signal has been gained up to about −28 dBV, while the noise content at 300 kHz and 1.2 MHz has been reduced very significantly to about −55 dBV and −45 dBV, respectively.

The circuit is operating with a switching frequency of 1.25 MHz, but because of the double sampling technique the input signal is effectively sampled at 2.5 MHz. The result is that the 1.25 MHz operating frequency is not aliased to the 0 Hz (or DC) frequency bin.

According to some examples, the noise gate circuit 355 includes a threshold reference select circuit. To generate one or more threshold voltages to use in detecting signal amplitude, the noise gate circuit 355 receives a reference voltage. In some examples, the reference voltage is provided by a voltage reference circuit 380 (e.g., a bandgap reference circuit) to provide a voltage having a specified reference voltage value (e.g., 1.2V-1.3V). In some examples, the voltage reference circuit 380 is included in the IC.

The threshold reference circuit 380 includes a divider circuit included on the IC and configured to divide down the reference voltage value to provide a selectable threshold voltage value to use in detecting signal amplitude. In some examples, divider circuit divides a reference voltage by a factor great than one hundred to generate a threshold voltage for comparison to an input signal amplitude. In certain examples, the reference voltage is divided by a factor of more than four hundred to generate a threshold voltage. This allows the noise gate circuit to generate the indication to mute one or both of the first and second circuit paths when the amplitude of the first, second or third electrical input signal is less than 1 mV.

In some examples, the divider circuit includes a switched capacitor divider circuit. In switched capacitor circuits, resistors are approximated by R=1/(Cₛ*f), where R is the approximated resistance, Cₛ is the switched capacitor value and f is the switching frequency. Using a switched capacitor divider circuit allows the voltage reference to be divided down by a factor greater than four hundred while the ratio between capacitor values in the switched capacitor circuit is much less.

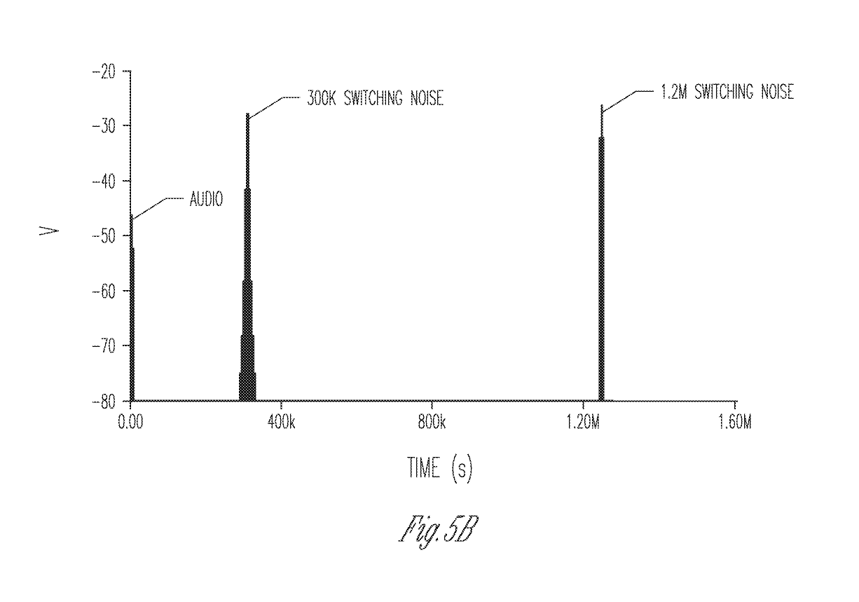

FIG. 6 shows an example of a switch cap divider circuit 600 for single ended signal. In the example, the circuit divides the reference voltage according to:

G˜(C1C2)/[(C1+C2+C3)*C4].

If C is a unit sized capacitor and C1=C2=C, C3=4C, and C4=8C, then

V_{ref,out}=V_{ref,in}/56.

If V_{ref,in} is 1.25V then V_{ref,out} is 22 mV.

Switched-capacitor circuits typically use capacitor ratios instead of absolute values of capacitors. The example shows a capacitor ratio of 8:1, which can be more accurate and easier to implement than trying to accurately have a ratio of 56:1. Some of the capacitors (e.g., C3 and C4) shown in Figure are actually arrays, or groups, of capacitors which can be switched in or out. In this way the gain/attenuation G is made programmable and/or selectable. As explained above, in some examples, the switching frequency of the switched capacitor divider is chosen to alias system frequencies to higher frequencies away from the audio frequency band.

The divider circuit divides the reference voltage value to provide a selectable first specified threshold voltage value. In some examples, the threshold reference circuit 380 provides one of seven selectable threshold values. In certain examples, a separate selectable value is used on each of the first and second circuit paths for independent detection of signal amplitudes. In certain examples, the threshold values are selectable by writing one or more registers in the digital circuitry 385.

In some examples, the noise gate circuit 355 includes a gain circuit to gain or amplify at least one of the first, second, and third electrical signals for a comparison to the selectable first specified threshold voltage value. This increases the range of signal amplitudes detectable by the noise gate circuit 355. In some examples, the generated threshold voltage value used for detection is filtered to remove noise from the detection threshold.

In some examples, the noise gate circuit includes a timer circuit integral to or communicatively coupled to the noise gate circuit 355. The noise gate circuit 355 is configured to generate the first indication when the amplitude of the first electrical signal decreases below the specified threshold amplitude value for a specified time duration. In some examples, the noise gate circuit provides an indication to mute the first circuit path 205 when a detected amplitude of the first electrical signal is below the first specified threshold value for a first specified time duration, and provides an indication to mute the second circuit path 225 when a detected amplitude of one or more of the second and third electrical signals is below the same or a second different specified threshold voltage value for the same or a second different specified time duration. In some examples, there are six selectable qualification times for the time duration, from 10 milliseconds (ms) to 640 ms before mute is activated by the control circuit 215. In some examples, a qualification time for the first circuit path is independently selectable from a qualification time for the second circuit path. In some examples, the noise gate circuit 355 generates an indication to unmute a circuit path when the input signal rises above the specified threshold for a qualification time.

The indication generated by the noise gate can be a noisy signal (e.g., when the electrical input signal is hovering about the threshold point). According to some examples, the noise gate circuit 355 incorporated post-processing of the amplitude detection to reject spurious noise hits. In some examples, the output of the noise gate circuit 355 includes a finite impulse response (FIR) low pass filter circuit to smooth the generation of at least one of the first and second indications. In some examples, the FIR is implemented in the digital circuitry 385 and the parameters of the FIR filtering are user programmable. For instance, the FIR may implement a running average of the indications generated by the noise gate circuit 355 and a user can program parameters related to how many samples are used in the average. Having the parameters be programmable allows the user to evaluate the effectiveness of the FIR filtering.

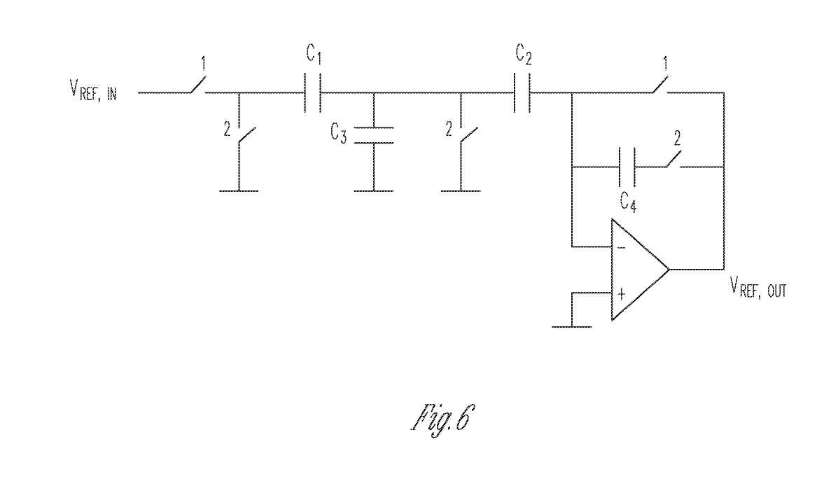

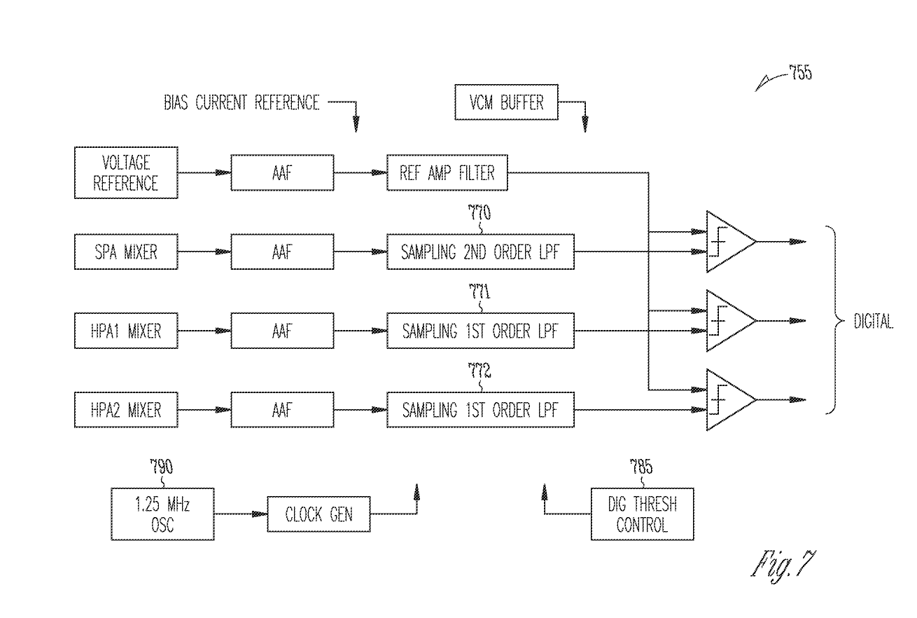

FIG. 7 shows another a block diagram of another example of a noise gate circuit 755. The noise gate circuit 755 monitors the first electrical input signal at the output of a signal mixer as shown in FIG. 1 and also monitors the second and third electrical signals at the output of mixer circuits. The noise gate circuit diagram shows the anti-aliasing functions (AAF) and filtering of the monitored signals. The signal from the first circuit path is filtered using a second order lowpass filter and the signals from the second circuit path are monitored using first order low pass filters.

The noise gate circuit diagram also shows that noise is reduced in the dividing and gaining of the voltage reference by anti-aliasing and filtering. The digital threshold control circuit 785 provides selection of detection threshold voltage values and detection qualification times.

Additional features can be included in the IC to further reduce noise. As explained previously the signal paths in the noise gate circuit 755 can be differential. Typically, signal path are single ended. Using differential signal paths rejects common mode noise.

In some examples, the IC includes a low drop out (LDO) regulator circuit electrically coupled to the oscillator circuit 790. The LDO circuit generates a regulated voltage that is substantially equal to the voltage amplitude of the first clock signal. In certain examples, the LDO circuit generates a regulated voltage of 2.0V from a 5V source. Use of an LDO circuit helps in power supply noise rejection.

In some examples, the sampling of the electrical signals is synchronous with the switched cap switching times and/or the switching times of the switching amplifier and charge pump. Synchronizing the sampling of the discrete-time sampling of the filters allow processing during “quiet times” of the switching. For switched capacitor circuits for instance, there are certain time periods when the next circuit block is processing signals. Synchronizing the sampling to avoid these certain time periods avoids the processing noise of the switched capacitor circuits.

In some examples, the noise gate circuit is isolated in the IC from the substrate. The noise gate can be formed in a tub or well and not in the substrate which can be charge pumped to zero volts.

Providing both analog and digital functionality on a single IC can be difficult especially when processing extremely small amplitude signals for audio applications. Providing mute and unmute capability can enhance the experience of a user of device that includes such an IC.

### Other Volume Control Features

FIG. 2 shows a block diagram of portions of an example of a single mixed signal IC that includes audio amplifiers to drive a speaker circuit path and a stereo headphone circuit path. Clipping and speaker damage can be eliminated through the use of automatic gain control (AGC) to limit the amplifier gain during high volume events or during V_{BATT} droop to control clipping.

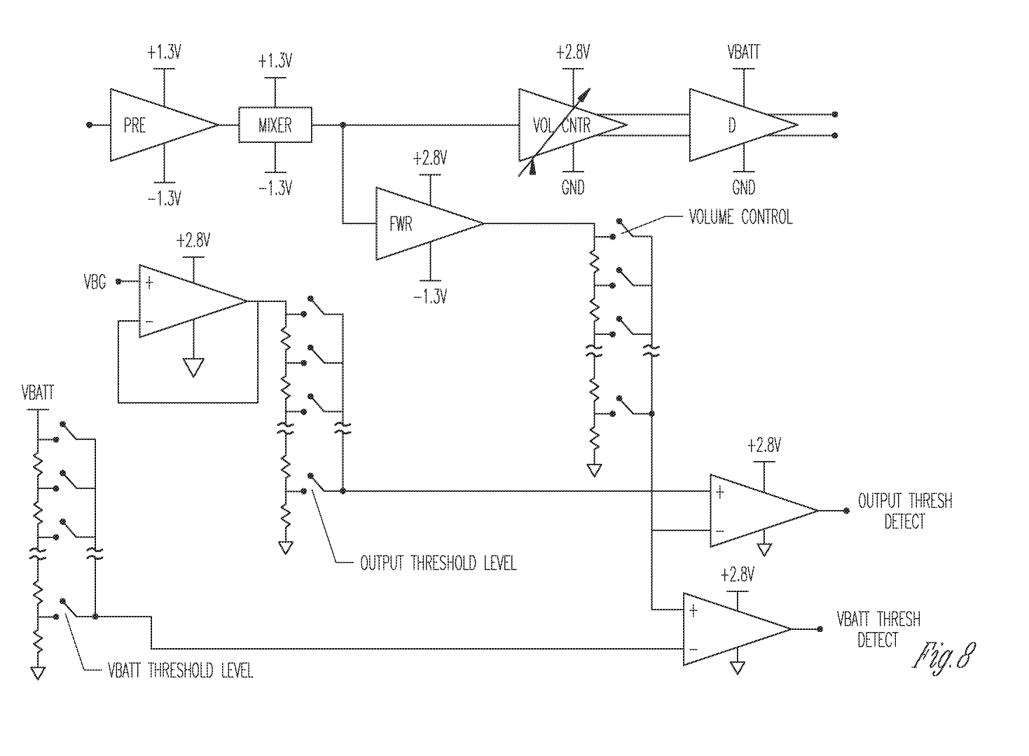

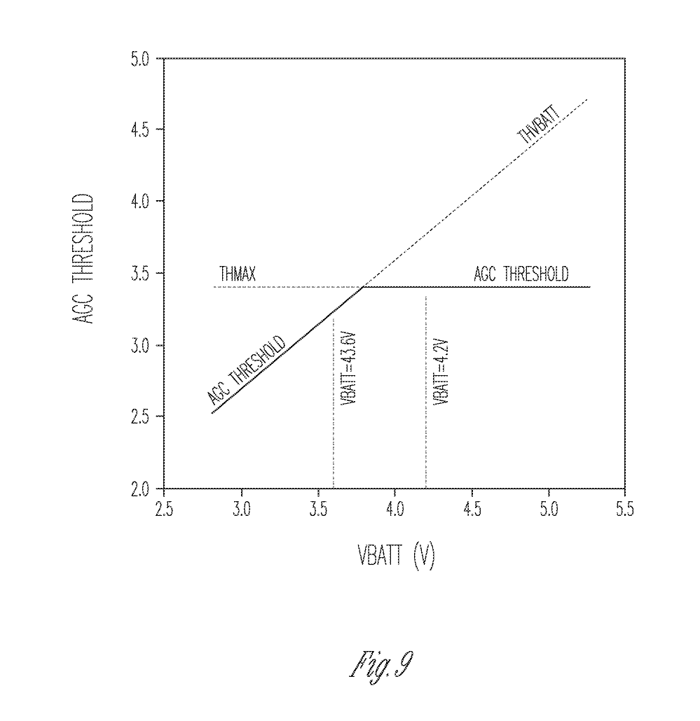

FIG. 8 shows an example of a circuit for threshold detection for AGC. The circuit is shown monitoring the speaker circuit path of FIG. 2. The AGC limits the output amplitude when a programmable threshold is reached. The threshold detection looks at V_{BATT} and the input signal amplitude to determine when the threshold enabling AGC is reached. FIG. 9 shows an example of variation of the AGC threshold with battery voltage. When AGC is initiated, the amplifier gain is limited to control clipping. The AGC gain is determined using V_{BATT}, the user volume setting, and the input signal amplitude. By limiting or lowering the gain, overdriving of the speaker is prevented and signal clipping is reduced.

Different options for adjusting the volume are programmable. In some examples, the volume control is programmed to change immediately. However, instantaneous changes can lead to distortion. This distortion can be reduced or eliminated by the use of volume ramping and zero crossing detection.

Volume ramping prevents distortion form abrupt changes in volume by creating ramp transitions for the volume instead of allowing transitions in large steps. One or both of the ramp rate and the ramp threshold can be user selectable to provide options for performance trade-offs. Examples of possible rates are 0.25, 2, 16, and 128 ms. In some examples, one or both of the attack ramp rates and the release ramp rates are programmable.

Zero crossing detection reduces noise during changes in volume steps by only changing the volume during a zero crossing of the input signal or waveform. In some examples, the volume is ramped and the volume is changed only during a zero crossing or at the ramp rate, whichever comes first. The result is that the volume will change no faster than the ramp rate.

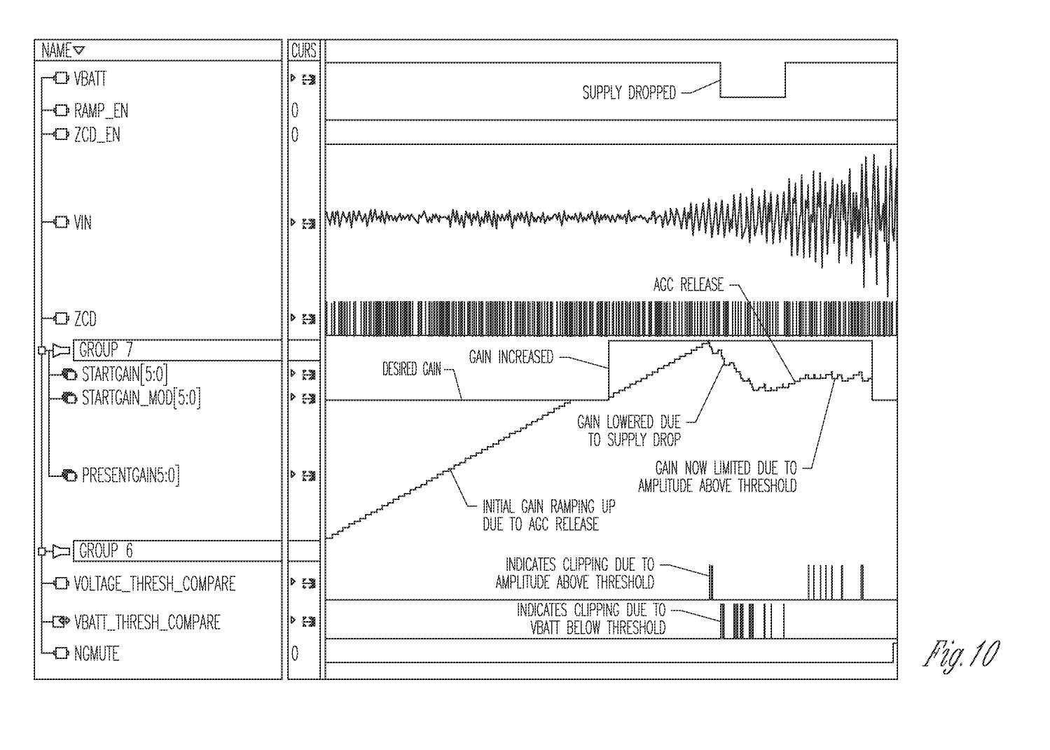

FIG. 10 shows an example simulation of the example of volume control described. The simulation shows the gains as analog values instead of digital numbered values for purposes of display. In the simulation shown, Startgain is user set, Startgain_mod is the gain set by the ramping and zero crossing detection, and Presentgain is Startgain_mod altered by the AGC. The simulation shows that the gain is ramped during startup and then the user gain is increased. The voltage supply drops during the simulation so the AGC lowers the gain to avoid clipping. When the supply is restored the simulation shows that increased signal amplitude causes the AGC to again lower the gain.

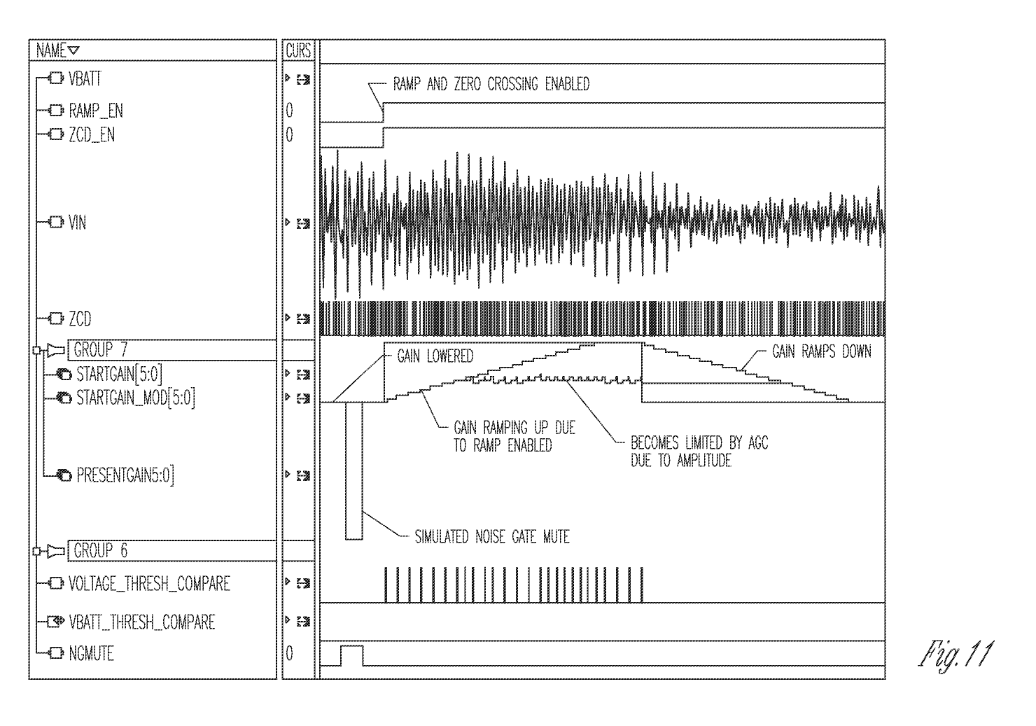

FIG. 11 shows another example simulation. The gain drops to zero when an indication to mute is received from a noise gate circuit. The gain is restored when the mute episode is finished. The simulation next shows that the raised with volume ramping and zero crossing detection enabled. The gain ramps up until it is high enough to cause clipping. The AGC then limits the gain. The gain is then dropped and the gain ramps down.

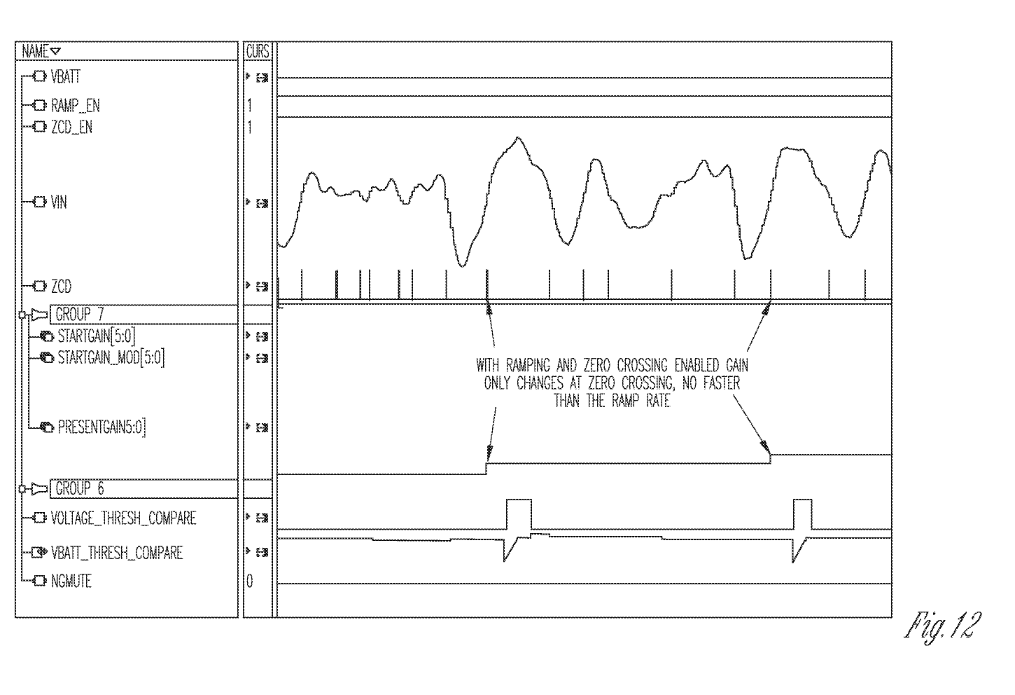

FIG. 12 shows a zoomed-in portion of the simulation of FIG. 11. The waveform shows how the gain only changes during a zero crossing of the input signal (vin). Because volume ramping is enabled, the gain only changes one volume step at a time.

### Additional Notes

Example 1 includes subject matter (such as an apparatus formed on single IC) comprising a first signal circuit path to process a first electrical signal that includes one or more signal frequencies in the audio frequency band, wherein the first signal circuit path includes a first amplifier circuit configured to provide a first output signal to a speaker load, a noise gate circuit configured to monitor the first electrical signal and generate a first indication when an amplitude of the first electrical signal decreases below a first specified threshold voltage value, and a control circuit communicatively coupled to the noise gate circuit and first signal circuit path, wherein the control circuit is configured to mute an output of the first signal circuit path according to the generated indication.

In Example 2, the subject matter of Example 1 can optionally include a second circuit path to process a second electrical signal and a third electrical signal each having a frequency in the audio frequency band, wherein the second and third electrical signals form a stereo signal pair, wherein the second circuit path is independent from the first circuit path and includes a second amplifier circuit and a third amplifier circuit to receive the second and third electrical signals and provide second and third output signals respectively, wherein the noise gate circuit can be optionally configured to generate a second indication when the amplitude of at least one of the second and third electrical signals decreases below the first specified threshold voltage value or a different second specified threshold voltage value, and wherein the control circuit can be optionally configured to mute outputs of the second and third amplifier circuits according to the detection circuit indication.

In Example 3, the first amplifier circuit of one or any combination of Examples 1-2 can optionally be a switching amplifier circuit configured to provide a first output signal to switch the speaker load between a circuit supply voltage and IC ground, and the noise gate circuit can optionally include a charge pump circuit communicatively coupled to the second and third amplifier circuits, wherein the charge pump is configured to generate a positive supply rail and a negative supply rail for the second and third amplifier circuits, and a discrete-time low pass filter circuit configured to filter at least one of the first electrical signal and the second and third electrical signals, wherein a sampling rate of the discrete-time filter reduces aliasing noise, due to switching of the switching amplifier and the charge pump circuit, at zero Hertz (0 Hz).

In Example 4, a switching frequency of the charge pump circuit of Example 3 can optionally vary based on the amplitude of one or both of the second and third electrical signals.

In Example 5, an output of the noise gate circuit of one or any combination of Examples 1-4 can optionally include a finite impulse response (FIR) low pass filter to smooth the generation of at least one of the first and second indications.

In Example 6, the first switching amplifier circuit of one or any combination of Examples 1-5 can optionally be a class D amplifier circuit and the second and third amplifier circuits can optionally be class G audio amplifier circuits.

In Example 7, the noise gate circuit of one or any combination of Examples 1-6 can optionally include a divider circuit included on the IC and configured to divide a reference voltage value to provide a selectable first specified threshold voltage value.

In Example 8, the noise gate circuit of one or any combination of Examples 1-7 can optionally include a gain circuit to gain at least one of the first, second, and third electrical signals for a comparison to the selectable first specified threshold voltage value.

In Example 9, the divider circuit of Example 8 can optionally include a switch capacitor divider circuit.

In Example 10, the subject matter of one or any combination of Examples 1-9 can optionally include a timer circuit integral to or communicatively coupled to the noise gate circuit, wherein the noise gate circuit is configured to generate the first indication when the amplitude of the first electrical signal decreases below the specified threshold amplitude value for a specified time duration.

In Example 11, the noise gate circuit of one or any combination of Examples 1-10 can optionally be configured to generate the indication control circuit to mute the first circuit path when the amplitude of the first electrical input signal is less than one millivolt (1 mV).

Example 12 can include subject matter or can optionally be combined with the subject matter of one or any combination of Examples 1-11 to include subject matter (such as a system) comprising a speaker and an IC. The IC comprises a first signal circuit path to process a first electrical signal that includes one or more signal frequencies in the audio frequency band, wherein the first signal circuit path includes a first amplifier circuit configured to provide a first output signal to the speaker, a noise gate circuit configured to monitor the first electrical signal and generate a first indication when an amplitude of the first electrical signal decreases below a first specified threshold voltage value, and a control circuit communicatively coupled to the noise gate circuit and first signal circuit path, wherein the control circuit is configured to mute an output of the switching amplifier circuit according to the generated indication.

In Example 13, the subject matter of Example 12 can optionally include an audio jack connector configured to receive an audio jack plug of a separate device, and the IC can optionally include a second circuit path to process a second electrical signal and a third electrical signal each having a frequency in the audio frequency band, wherein the second and third electrical signals form a stereo signal pair, wherein the second circuit path is independent from the first circuit path and includes a second amplifier circuit and a third amplifier circuit to receive the second and third electrical signals and provide second and third output signals respectively, wherein the noise gate circuit can optionally be configured to generate a second indication when the amplitude of at least one of the second and third electrical signals decreases below the first specified threshold voltage value or a different second specified threshold voltage value, and wherein the control circuit can optionally be configured to mute outputs of the second and third amplifier circuits according to the detection circuit indication.

In Example 14, the first amplifier circuit of one or any combination of Examples 12 and 13 can optionally be a switching amplifier circuit configured to provide a first output signal to switch the speaker load between a circuit supply voltage and IC ground, and the noise gate circuit can optionally include a charge pump circuit communicatively coupled to the second and third amplifier circuits, wherein the charge pump is configured to generate a positive supply rail and a negative supply rail for the second and third amplifier circuits, and a discrete-time low pass filter circuit configured to filter at least one of the first electrical signal and the stereo signal pair, wherein a sampling rate of the discrete-time filter reduces aliasing noise, due to switching of the switching amplifier and the charge pump circuit, at zero Hertz (0 Hz).

Example 15 can include subject matter, or can optionally be combined with the subject matter of one or any combination of Examples 1-14 to include subject matter (such as a method, a means for performing acts, or a machine-readable medium including instructions that, when performed by the machine, cause the machine to perform acts) comprising processing a first electrical input signal having a signal frequency in an audio frequency band using a first circuit path on a single integrated circuit (IC), providing a first output signal at an output of the first circuit path output to a speaker load, and muting the first circuit path output when detecting that the amplitude of the first electrical input signal decreases below a specified threshold amplitude value.

Such subject matter can include means for processing a first electrical input signal having a signal frequency in an audio frequency band, an illustrative example of which is one or more circuit paths in the IC. Such subject matter can include means for providing a first output signal at an output of the first circuit path output to a speaker load, an illustrative example of which is an amplifier circuit, such as a switching amplifier circuit, class D amplifier circuit, class G amplifier circuit or other amplifier circuit. Such subject matter can include means for muting the first circuit path output when detecting that the amplitude of the first electrical input signal decreases below a specified threshold amplitude value, an illustrative example if which is a detection circuit and a control circuit, such as a custom logic circuit or processor for example.

In Example 16, the subject matter of Example 15 can optionally include processing second and third electrical signals using a second circuit path on the single IC, wherein the second and third electrical signals each have a signal frequency in the audio frequency range and form a stereo signal pair, and wherein the second circuit path is independent of the first circuit path, and muting an output of the second circuit path when detecting that the amplitude of at least one of the second and third electrical signals decreases below the specified threshold amplitude value.

In Example 17, the providing the first output signal to a speaker load of one or any combination of Examples 15 and 16 can optionally include switching the speaker load between a circuit supply voltage and IC ground, and the subject matter can optionally include providing positive and negative supply rails for the second circuit path using a charge pump circuit included in the single IC, and filtering at least one of the first electrical signal and the stereo signal pair using at least one discrete-time low pass filter, wherein a sampling rate of the discrete-time filter reduces aliasing noise, due to switching of the speaker load and the charge pump circuit, at zero Hertz (0 Hz).

In Example 18, the processing the first, second, and third electrical signals of one or any combination of Examples 16 and 17 optionally includes converting the first, second, and third electrical signals to differential signals.

In Example 19, the muting the switching amplifier of one or any combination of Examples 15-18 can optionally include muting the switching amplifier when the amplitude of the first electrical signal decreases below a selectable threshold amplitude value.

In Example 20, the subject matter of one or any combination of Examples 15-19 can optionally include generating a voltage having a specified reference voltage value, and dividing the reference voltage value on the single IC to generate the selectable specified voltage threshold value.

In Example 21, the subject matter of one or any combination of Examples 15-20 can optionally include amplifying the first electrical signal for a comparison to the specified threshold amplitude value.

In Example 22, muting a circuit path output of one or any combination of Examples 15-21 can optionally includes muting the switching amplifier when the amplitude of the first electrical signal decreases below the specified threshold amplitude value for a specified time duration.

In Example 23, the detecting an electrical input signal amplitude below a specified threshold amplitude value of one or any combination of Examples 15-22 can optionally include smoothing an indication of the detection using a finite impulse response (FIR) low pass filter that is user programmable.

In Example 24, the processing a first electrical input signal of one or any combination of Examples 15-24 can optionally include processing a first electrical input signal having a signal amplitude less than approximately ten millivolts (10 mV).

In Example 25, the muting the first circuit path output of one or any combination of Examples 15-25 can optionally include muting the switching amplifier when the amplitude of the first electrical signal decreases below approximately one millivolt (1 mV).

Example 26 can include, or can optionally be combined with any portion or combination of any portions of any one or more of Examples 1-25 to include, subject matter (such as an apparatus) that can include means for performing any one or more of the functions of Examples 1-25, or a machine-readable medium including instructions that, when performed by a machine, cause the machine to perform any one or more of the functions of Examples 1-25.

These non-limiting examples can be combined in any permutation or combination.

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. Method examples described herein can be machine or computer-implemented at least in part.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. An apparatus formed on a single integrated circuit (IC), the apparatus comprising:
a first signal circuit path to process a first electrical signal that includes one or more signal frequencies in the audio frequency band, wherein the first signal circuit path includes a first amplifier circuit configured to provide a first output signal to a speaker load;
a noise gate circuit configured to monitor the first electrical signal and generate a first indication when an amplitude of the first electrical signal decreases below a first specified threshold voltage value; and
a control circuit communicatively coupled to the noise gate circuit and first signal circuit path, wherein the control circuit is configured to mute an output of the first signal circuit path according to the generated indication.

2. The apparatus of claim 1, including:
a second circuit path to process a second electrical signal and a third electrical signal each having a frequency in the audio frequency band, wherein the second and third electrical signals form a stereo signal pair, wherein the second circuit path is independent from the first circuit path and includes a second amplifier circuit and a third amplifier circuit to receive the second and third electrical signals and provide second and third output signals respectively,
wherein the noise gate circuit is configured to generate a second indication when the amplitude of at least one of the second and third electrical signals decreases below the first specified threshold voltage value or a different second specified threshold voltage value, and
wherein the control circuit is configured to mute outputs of the second and third amplifier circuits according to the detection circuit indication.

3. The apparatus of claim 2,
wherein the first amplifier circuit is a switching amplifier circuit configured to provide a first output signal to switch the speaker load between a circuit supply voltage and IC ground, and
wherein the noise gate circuit includes:
a charge pump circuit communicatively coupled to the second and third amplifier circuits, wherein the charge pump is configured to generate a positive supply rail and a negative supply rail for the second and third amplifier circuits; and
a discrete-time low pass filter circuit configured to filter at least one of the first electrical signal and the second and third electrical signals, wherein a sampling rate of the discrete-time filter reduces aliasing noise, due to switching of the switching amplifier and the charge pump circuit, at zero Hertz (0 Hz).

4. The apparatus of claim 3, wherein a switching frequency of the charge pump circuit is variable based on the amplitude of one or both of the second and third electrical signals.

5. The apparatus of claim 2, wherein an output of the noise gate circuit includes a finite impulse response (FIR) low pass filter to smooth the generation of at least one of the first and second indications.

6. The apparatus of claim 2, wherein the first switching amplifier circuit is a class D amplifier circuit and the second and third amplifier circuits are class G audio amplifier circuits.

7. The apparatus of claim 1, wherein the noise gate circuit includes a divider circuit included on the IC and configured to divide a reference voltage value to provide a selectable first specified threshold voltage value.

8. The apparatus of claim 7, wherein the noise gate circuit includes a gain circuit to gain at least one of the first, second, and third electrical signals for a comparison to the selectable first specified threshold voltage value.

9. The apparatus of claim 7, wherein the divider circuit includes a switch capacitor divider circuit.

10. The apparatus of claim 1, including a timer circuit integral to or communicatively coupled to the noise gate circuit, wherein the noise gate circuit is configured to generate the first indication when the amplitude of the first electrical signal decreases below the specified threshold amplitude value for a specified time duration.

11. The apparatus of claim 1, wherein the noise gate circuit is configured to generate the indication control circuit to mute the first circuit path when the amplitude of the first electrical input signal is less than one millivolt (1 mV).

12. A system comprising:
a speaker and an IC, the IC comprising:
a first signal circuit path to process a first electrical signal that includes one or more signal frequencies in the audio frequency band, wherein the first signal circuit path includes a first amplifier circuit configured to provide a first output signal to the speaker;
a noise gate circuit configured to monitor the first electrical signal and generate a first indication when an amplitude of the first electrical signal decreases below a first specified threshold voltage value; and
a control circuit communicatively coupled to the noise gate circuit and first signal circuit path, wherein the control circuit is configured to mute an output of the switching amplifier circuit according to the generated indication.

13. The system of claim 12, including:
an audio jack connector configured to receive an audio jack plug of a separate device, and wherein the IC includes:
a second circuit path to process a second electrical signal and a third electrical signal each having a frequency in the audio frequency band, wherein the second and third electrical signals form a stereo signal pair, wherein the second circuit path is independent from the first circuit path and includes a second amplifier circuit and a third amplifier circuit to receive the second and third electrical signals and provide second and third output signals respectively,
wherein the noise gate circuit is configured to generate a second indication when the amplitude of at least one of the second and third electrical signals decreases below the first specified threshold voltage value or a different second specified threshold voltage value, and
wherein the control circuit is configured to mute outputs of the second and third amplifier circuits according to the detection circuit indication.

14. The system of claim 13,
wherein the first amplifier circuit is a switching amplifier circuit configured to provide a first output signal to switch the speaker load between a circuit supply voltage and IC ground, and
wherein the noise gate circuit includes:
a charge pump circuit communicatively coupled to the second and third amplifier circuits, wherein the charge pump is configured to generate a positive supply rail and a negative supply rail for the second and third amplifier circuits; and
a discrete-time low pass filter circuit configured to filter at least one of the first electrical signal and the stereo signal pair, wherein a sampling rate of the discrete-time filter reduces aliasing noise, due to switching of the switching amplifier and the charge pump circuit, at zero Hertz (0 Hz).

15. A method comprising:
processing a first electrical input signal having a signal frequency in an audio frequency band using a first circuit path on a single integrated circuit (IC);
providing a first output signal at an output of the first circuit path output to a speaker load; and
muting the first circuit path output when detecting that the amplitude of the first electrical input signal decreases below a specified threshold amplitude value.

16. The method of claim 15, including:
processing second and third electrical signals using a second circuit path on the single IC, wherein the second and third electrical signals each have a signal frequency in the audio frequency range and form a stereo signal pair, and wherein the second circuit path is independent of the first circuit path; and
muting an output of the second circuit path when detecting that the amplitude of at least one of the second and third electrical signals decreases below the specified threshold amplitude value.

17. The method of claim 16, wherein providing the first output signal to a speaker load includes switching the speaker load between a circuit supply voltage and IC ground; and wherein the method includes:
providing positive and negative supply rails for the second circuit path using a charge pump circuit included in the single IC; and
filtering at least one of the first electrical signal and the stereo signal pair using at least one discrete-time low pass filter, wherein a sampling rate of the discrete-time filter reduces aliasing noise, due to switching of the speaker load and the charge pump circuit, at zero Hertz (0 Hz).

18. The method of claim 16, wherein processing the first, second, and third electrical signals includes converting the first, second, and third electrical signals to differential signals.

19. The method of claim 15, wherein muting the switching amplifier includes muting the switching amplifier when the amplitude of the first electrical signal decreases below a selectable threshold amplitude value.

20. The method of claim 15, including:
generating a voltage having a specified reference voltage value; and
dividing the reference voltage value on the single IC to generate the selectable specified voltage threshold value.

21. The method of claim 20, including amplifying the first electrical signal for a comparison to the specified threshold amplitude value.

22. The method of claim 15, wherein muting the switching amplifier includes muting the first circuit path output when the amplitude of the first electrical signal decreases below the specified threshold amplitude value for a specified time duration.

23. The method of claim 15, wherein detecting an electrical input signal amplitude below a specified threshold amplitude value includes smoothing an indication of the detection using a finite impulse response (FIR) low pass filter that is user programmable.

24. The method of claim 15, wherein processing a first electrical input signal includes processing a first electrical input signal having a signal amplitude less than approximately ten millivolts (10 mV).

25. The method of claim 15, wherein muting the first circuit path output includes muting the switching amplifier when the amplitude of the first electrical signal decreases below approximately one millivolt (1 mV).

26. An apparatus comprising:
means for processing a first electrical input signal having a signal frequency in an audio frequency band using a first circuit path on a single integrated circuit (IC);
means for providing a first output signal at an output of the first circuit path output to a speaker load; and
means for muting the first circuit path output when detecting that the amplitude of the first electrical input signal decreases below a specified threshold amplitude value.
